(19) United States
(12) Patent Application Publication
(10) Pub. No.: US 2011/0241200 A1
(43) Pub. Date: Oct. 6, 2011

(54) ULTRA LOW DIELECTRIC CONSTANT MATERIAL WITH ENHANCED MECHANICAL PROPERTIES

(75) Inventors: CHRISTOS D. DIMITRAKOPOULOS, Baldwin Place, NY (US); Stephen M. Gates, Ossining, NY (US); Alfred Grill, White Plains, NY (US)

(73) Assignee: International Business Machines Corporation, Armonk, NY (US)

(21) Appl. No.: 12/753,983

(22) Filed: Apr. 5, 2010

(51) Int. Cl. H01L 23/522; B05D 3/06; C04B 35/52

(52) U.S. Cl. 257/734; 427/509; 501/134; 257/E23.142

(57) ABSTRACT

An ultra low dielectric constant material is disclosed. The ultra-low dielectric constant material comprises a three dimensional random network porous dielectric comprising atoms of Si, C, O, and H. The ultra-low dielectric constant material also comprises a dielectric constant of not more than 2.6. The ultra-low dielectric constant material further comprises a carbon concentration of at least 15% and a content of carbon that is bonded as —CH2-groups, wherein a concentration of carbon is greater than a concentration of carbon in an ultra low dielectric constant material formed by using a single step ultra-violet curing process.

### FIELD OF THE INVENTION

The present invention generally relates to dielectric materials, and more particularly relates to carbon doped (C doped) or organosilicate glass materials.

### BACKGROUND OF THE INVENTION

Current back-end-of-line (BEOL) fabrication processes often involve the use of low k and ultra low k (ULK) dielectric materials. These materials belong to the class of organosilicate glasses, and are often called SiCOH denoting the elements contained in these films, which include silicon (Si), carbon (C), oxygen (O), and hydrogen (H). At k values below 2.7, this material is called porous SiCOH (pSiCOH). In future technology nodes, ULK dielectrics with a lower k will be needed to counteract the increase in RC delay resulting from the continuously diminishing critical dimensions (CD) of interconnect components. One way to reduce k is to increase the porosity of previous ULK films. However this process has the undesirable effect of weakening the mechanical properties of ULK films.

Also, when forming BEOL interconnect structures with increasingly smaller dimensions, dimension control becomes a problem when etching the damascene trench structure. The processes of etch and resist strip creates a damaged (C-depleted) layer on the trench and via sidewalls, an effect known as plasma-induced damage (PID). The layer that has been affected by PID has a higher k value than the pristine pSiCOH and is more hydrophilic. Another problem with many BEOL interconnect structures formed in a pSiCOH dielectric is that they experience water degradation.

### SUMMARY OF THE INVENTION

In one embodiment, an ultra low dielectric constant material is disclosed. The ultra-low dielectric constant material comprises a three dimensional random network porous dielectric comprising atoms of Si, C, O, and H. The ultra-low dielectric constant material also comprises a dielectric constant of not more than 2.6. The ultra-low dielectric constant material further comprises a carbon concentration of at least 15% and a content of carbon that is bonded as —CH2-groups, wherein a concentration of carbon is greater than a concentration of carbon in an ultra low dielectric constant material formed by using a single step ultra-violet curing process.

In another embodiment, a method for fabricating an ultra low dielectric constant material is disclosed. The method comprises placing a substrate into a deposition reactor. A first precursor is flowed into the deposition reactor, wherein the first precursor is a matrix precursor comprising at least Si and C atoms. A second precursor is flowed into the deposition reactor, wherein the second precursor is a porogen precursor comprising at least C and H atoms. A preliminary film is deposited onto the substrate based on the first and second precursors. A first ultraviolet curing step is performed on the substrate comprising the preliminary film at a first temperature. A second ultraviolet curing step is formed on the substrate comprising the preliminary film at a second temperature.

In yet another embodiment, an electronic structure comprising one or more layers of insulating material as at least one or intralevel and interlevel dielectrics in a wiring structure is disclosed. The electronic structure comprises a pre-processed semi-conducting substrate comprising a first region of metal embedded in a first layer of insulating material. A first region of conductor is embedded in a second layer of insulating material formed of an ultralow-k material. The ultralow-k material comprising Si, C, O and H, and a multiplicity of nanometer-sized pores. The ultralow-k material comprises a dielectric constant of not more than about 2.6 and comprising a carbon concentration of at least 15% and a content of carbon that is bonded as —CH2-groups, wherein a concentration of carbon is greater than a concentration of carbon in an ultra low dielectric constant material formed by using a single step ultra-violet curing process. The second layer of insulating material is in intimate contact with the first layer of insulating material. The first region of conductor is in electrical communication with the first region of metal. A second region of conductor is in electrical communication with the first region of conductor and being embedded in a third layer of insulating material comprising the ultralow-k material. The third layer of insulating material is in intimate contact with the second layer of insulating material.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention, in which:

FIG. 1 illustrates a bar graph plot of the relative Young's modulus for pSiCOH dielectrics that compares an ultra low dielectric constant material according to one embodiment of the present invention to a conventional material prepared with the same deposition step and a single UV cure step.

FIG. 2 illustrates a selected region of FTIR spectra of ULK dielectric materials according to one embodiment of the present invention vs a conventional pSiCOH material;

FIG. 3 illustrates solid state ¹³C NMR spectra of a ULK dielectric material according to one embodiment of the present invention vs the spectrum of a conventional pSiCOH material;

FIG. 4 shows a plot of the carbon percentage as measured by XPS vs a second UV curing step time for a ULK dielectric material according to one embodiment of the present invention.

FIG. 5 is an enlarged, cross-sectional view of one example of an electronic device having an intralevel dielectric layer and an interlevel dielectric layer formed using the stable low or ultra low k SiCOH dielectric material according to one embodiment of the present invention;

FIG. 6 is an enlarged, cross-sectional view of one example of the electronic structure of FIG. 4 having an additional diffusion barrier dielectric cap layer deposited on top of the low or ultra low k SiCOH dielectric material according to one embodiment of the present invention;

FIG. 7 is an enlarged, cross-sectional view of one example of the electronic structure of FIG. 5 having an additional RIE hard mask/polish-stop dielectric cap layer and a dielectric cap diffusion barrier layer according to one embodiment of the present invention;

FIG. 8 is an enlarged, cross-sectional view of one example of the electronic structure of FIG. 6 having additional RIE hard mask/polish-stop dielectric layers deposited on top of the stable low or ultra low k SiCOH dielectric material according to one embodiment of the present invention; and

FIG. 9 is an operational flow diagram illustrating one process for forming an ultra low SiCOH dielectric material according to one embodiment of the present invention.

### DETAILED DESCRIPTION

As required, detailed embodiments of the present invention are disclosed herein; however, it is to be understood that the disclosed embodiments are merely examples of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure and function. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically. Plural and singular terms are the same unless expressly stated otherwise.

Overview

ULK dielectrics with k below 2.7 can be used to counteract the increase in RC delay resulting from the continuously diminishing critical dimensions (CD) of interconnect components. The porosity of previous ULK films can be increased to reduce k of these materials. As discussed above, this has the undesirable effect of weakening the mechanical properties of ULK films. Another way to reduce k is to increase the Si—C bond content to Si—O bond content ratio, as Si—C bonds are less polar than Si—O bonds. However, the Si—O based dielectrics are prone to stress corrosion cracking.

Organic polymer dielectrics have a fracture toughness higher than organosilicate glasses and are not prone to stress corrosion cracking (as are the Si—O based dielectrics). This suggests that the addition of more organic polymer content and more Si—C bonds to SiCOH dielectrics can decrease the effects of water degradation and increase the nonlinear energy dissipation mechanisms such as plasticity. Addition of more organic polymer content to SiCOH can lead to a dielectric with increased fracture toughness and decreased environmental sensitivity.

Plasma processes, such as reactive ion etching (RIE) and resist stripping (ashing) involved in patterning porous SiCOH ULK dielectrics, have been shown to negatively affect the surface of the resulting patterns. Such plasma-induced damage (PID) effects include demethylation, and, more generally, reduction in the C-content of the surface-most part of the dielectric. This results in a more hydrophilic surface, an increase in its dielectric constant, and increased rate of removal of this affected layer by dilute HF cleaning steps, as compared to pristine dielectric. RIE damage can be reduced by increasing the C content of pSiCOH with species other than the usual Si—CH3 terminal groups, especially by introducing stable carbosilane bonds in the SiCOH material (Si—CH2-Si). However, conventional ULK dielectric materials have weak mechanical properties with a low k elemental composition configuration.

Therefore, various embodiments of the present invention provide an ULK dielectric material with a given dielectric constant and a given carbon concentration that overcomes the problems discussed above. In particular, various embodiments provide a porous low k dielectric constant material comprising atoms of Si, C, O and H (hereinafter “pSiCOH”) having a dielectric constant of not more than 2.6, with higher C content as compared to a conventional SiCOH material with the same k value.

For example, in one or more embodiments, a standard two precursor PECVD mix in combination with novel multistep UV (Ultraviolet) cure schemes is used to create films with a target k of k<2.1. The multistep UV cure schemes of one or more embodiments involve a first UV cure step at one temperature and a second UV cure step at another, higher temperature. Utilizing two or more UV curing steps improves the properties of the dielectric material. This results in a UV stable (thus very stable) C-containing species that comprise CH₂ (methylene) groups, while achieving the targeted k<2.1. Furthermore, these films have mechanical properties rivaling those of three-precursor films with k˜2.2. Therefore, various embodiments, provide a dielectric material comprised of Si, C, O, and H (pSiCOH) in which the percentage of carbon as measured by X-ray photoelectron spectroscopy (XPS), hereafter called the “C content”, is higher than conventional pSiCOH dielectrics. Another advantage of the ULK dielectric material is that, in one embodiment, it is a pSiCOH dielectric material with elastic modulus higher than a conventional pSiCOH dielectric at the same k value. An additional advantage is that one or more embodiments provide appropriate methods for preparation of the SiCOH dielectric material. A further advantage of one or more embodiments is that an electronic structure is provided that incorporates the SiCOH material as an intralevel and/or interlevel dielectric in a BEOL wiring structure.

ULK Dielectric Material

As discussed above, various embodiments of the present invention provide a porous dielectric material that comprises a matrix of a hydrogenated oxidized silicon carbon material (SiCOH) comprising elements of Si, C, O, and H in a covalently bonded tri-dimensional network and that has a dielectric constant of about 2.6 or less. The pSiCOH dielectrics of or one or more embodiments have an elastic modulus that is greater than pSiCOH dielectrics prepared using standard methods of fabrication. The term “tri-dimensional network” is used throughout this disclosure to denote a pSiCOH dielectric material that includes silicon, carbon, oxygen, and hydrogen that are interconnected and interrelated in the x, y, and z directions. It should be noted that the dielectric material of one or more embodiments of the present invention does not contain a regularly repeated structural unit, but instead comprises a random tri-dimensional (i.e., three-dimensional) structure.

In one or more embodiments, the C, Si, and O content of the SiCOH dielectric material is as follows: between about 5 and about 40, with an example range of from about 15 to about 35, atomic percent of C; between about 5 and about 50, with an example range of from about 15 to about 30, atomic percent of Si; between 0 and about 50, with an example range of from about 15 to about 35, atomic percent of O.

In one embodiment, the SiCOH dielectric materials are typically deposited using plasma enhanced chemical vapor deposition (PECVD). In addition to PECVD, the SiCOH dielectric materials can be formed utilizing chemical vapor deposition (CVD), high-density plasma (HDP), pulsed PECVD, spin-on application, or other related methods. The following are examples illustrating material and processing embodiments of the present invention.

In one embodiment, a stable ultra low k SiCOH dielectric material is formed that has a dielectric constant (or k value) of about 1.8 to 2.6. In the deposition process, such as (but not limited to) a PECVD process, a substrate is placed in a PECVD reactor on a heated wafer chuck and a reactive gas mixture is added to the reactor. In one non-limiting example, the substrate is a 300 mm Si wafer and the reactor is a 300 mm production tool. The SiCOH dielectric material is formed by providing at least a first matrix precursor (liquid, gas, or vapor) comprising atoms of Si, C, O, and H, and an inert carrier gas such as He or Ar, into the reactor. A film is then derived from the first precursor onto a suitable substrate utilizing conditions that are effective in forming the SiCOH dielectric material of at least this embodiment. Also, in one embodiment, the first precursor can be mixed with an oxidizing agent such as O₂, CO₂, or a combination thereof, thereby stabilizing the reactants in the reactor and improving the uniformity of the dielectric film deposited on the substrate. In another embodiment, in addition to the first precursor, the reactive gas mixture also comprises a second porogen precursor (gas, liquid, or vapor) comprising atoms of C, H, and optionally O, F, and N. For example, the second porogen precursor can be, but is not limited to, bicycloheptadiene (BCHD), also called norbornadiene (NBD).

The conditions used for the deposition step discussed above may vary depending on the desired final dielectric constant of the SiCOH dielectric material of one or more embodiments of the present invention. Examples of a few conditions that can used for providing a stable dielectric material comprising elements of Si, C, O, H that has a dielectric constant of about 1.8 to 2.6 or less include: setting the wafer chuck temperature at between about 200° C. and about 425° C.; setting the reactor pressure at around 8 Torr; setting the high frequency RF power that is applied to the gas distribution plate between about 75 W and about 1000 W, e.g., 700 W; setting the first precursor flow rate for DEMS to 1075 mg/minute; setting the second porogen precursor flow rate for BCHD to 1900 mg/minute; and setting the flow of an oxidizing gas such as O₂ to between about 10 sccm to about 1000 sccm (e.g., 125 sccm). It should be noted that these are examples of only one set of settings applicable to embodiments of the present invention and do not limit the present invention in any way. Very different conditions may be used for the deposition step within the invention, according to the equipment used.

In the example above, the application of the RF power results in the deposition of a preliminary film onto the substrate, using an application time of 60 to 90 seconds. The preliminary film is similar to the multiphase or dual phase films discussed in U.S. Pat. Nos. 6,147,009, 6,312,793, 6,441,491, 6,437,443, 6,541,398, 6,479,110 B2, and 6,497,963, which are hereby incorporated by reference in their entirety.

Once the preliminary film is deposited, the substrate with comprising the preliminary file is transferred to wafer chuck in a UV cure tool (such as, but not limited to a 300 mm production UV cure tool). The UV treatment tool may be connected to the deposition tool (“clustered”), or may be a separate tool. The wafer chuck is heated to a first temperature such as, but not limited to, 300° C. and broad band UV radiation is applied for a given amount of time such as, but not limited, to between about 10 to 1000 seconds (e.g., 300 seconds). This process results in a reaction of a fraction of the porogen phase and removal of a fraction of the porogen phase. The substrate is then transferred to another wafer chuck of a second UV cure tool (or remains on the same wafer chuck within the same UV cure tool). The wafer chuck is then heated to a second temperature such as, but not limited to, 385° C. and broad band UV radiation is applied for a given amount of time such as, but not limited, to between about 10 to 1000 seconds (e.g., 300 seconds). This process results in the removal of the majority of the porogen phase. In another embodiment, after the preliminary film is deposited on the substrate, as discussed above, the substrate with the preliminary film is placed on a wafer chuck in a UV cure tool.

The temperature of the wafer chuck is set at a first temperature and broad band UV radiation is applied for a given amount of time such as, but not limited, to between about 10 to 1000 seconds (e.g., 300 seconds). The substrate is then removed from the UV cure tool and the wafer chuck is then increased to a second higher temperature. The substrate with the preliminary film is then placed back into the same UV cure tool and broad band UV radiation is applied for a given amount of time such as, but not limited, to between about 10 to 1000 seconds (e.g., 300 seconds). The curing time of between about 10 to 1000 seconds can be varied depending on the desired properties of the inventive material.

Measurements conducted on the ULK dielectric material of one or more of the embodiments discussed above are as follows. The k value was measured in an aluminum gate MIS structure with the substrate stabilized at 150° C. on a hot plate and was 2.1. The modulus was measured by nanoindentation and was 2.9+/−0.2 GPa using a film thickness of approximately 400 nm. The composition (excluding H) was measured by XPS (X-ray photoelectron spectroscopy), and the carbon content was 41%. It should be noted that these measurements are associated with only one configuration of the ULK dielectric material and other measurements can be obtained as well. The properties of the ULK dielectric material of one or more embodiments of the present invention are shown in Table 1 below as compared to a conventional pSiCOH material prepared using one UV cure step, which is the current standard method.

TABLE 1

| Material | K value | E, GPa | % C by XPS |
|---|---|---|---|
| pSiCOH of the 1^{st} | 2.1 | 2.9 +/− 0.2 | 41 |
| process embodiment | | | |
| Conventional pSiCOH | 2.0 | 2.35 +/− 0.1 | 36 |
| using a single UV cure | | | |
| step | | | |

As can be seen from the table, the pSiCOH of the embodiment discussed above has a k value of 2.1, an elasticity modulus of 2.9+/−0.2 GPa, and has a carbon concentration of 41%. The conventional pSiCOH using a single UV curing step has a k value of 2.0, an elasticity modulus of 2.35+/−0.1 GPa, and has a carbon concentration of 36%. Therefore, one or more embodiments of the present invention provide a pSiCOH dielectric material with a higher carbon content than conventional pSiCOH dielectrics and with an elastic modulus higher than a conventional pSiCOH dielectric at approximately the same k value.

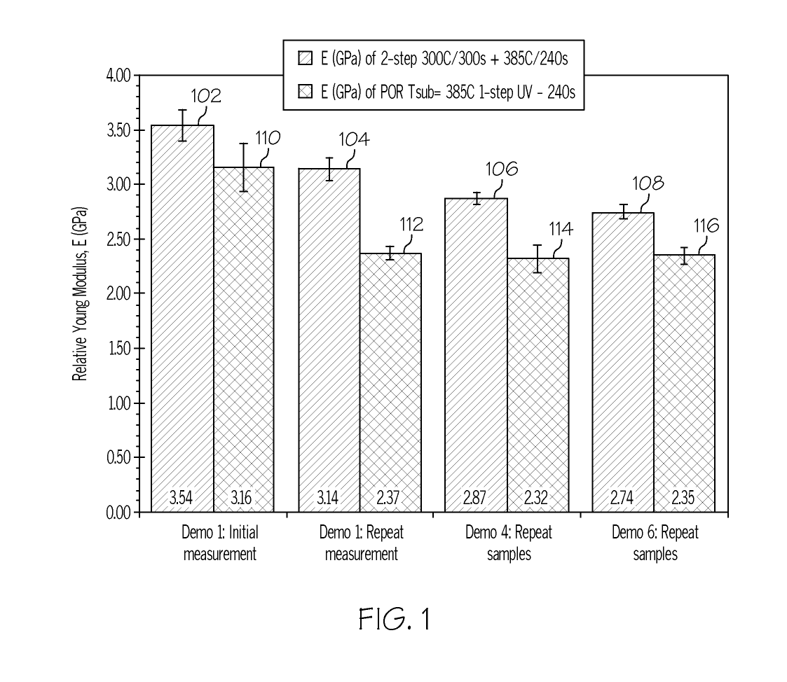

FIG. 1 shows a graph of Young's (elastic) modulus for four pairs of pSiCOH films, each pair deposited with the same deposition recipe. The first set of bars 902, 904, 906, 908, in each pair plots the Young's (elastic) modulus of the pSiCOH discussed in the two-step UV cure process above. The second set of bars 110, 112, 114, 116 in each pair plots the Young's (elastic) modulus of conventional pSiCOH (i.e. cured in a single-step UV cure process).

Table 2 below shows the Young's modulus and k for the first pair illustrated in FIG. 1. The k values are the same within experimental error. The difference in Young's modulus is greater than the experimental error.

TABLE 2

| | | AI dot K @ 150 C. |
|---|---|---|
| Sample | E (GPa) | A- step thk. |
| Inventive material: 2-step | 3.54 | 2.08 |
| UV cure of k = 2.0-2.1 | | |
| pSiCOH at 300 C./300 s + | | |
| 385 C./240 s | | |
| Conventional pSiCOH: | 3.16 | 2.11 |
| Single step POR UV cure | | |
| of k-2.0-2.1 pSiCOH at | | |
| 385 C. for 240 s | | |

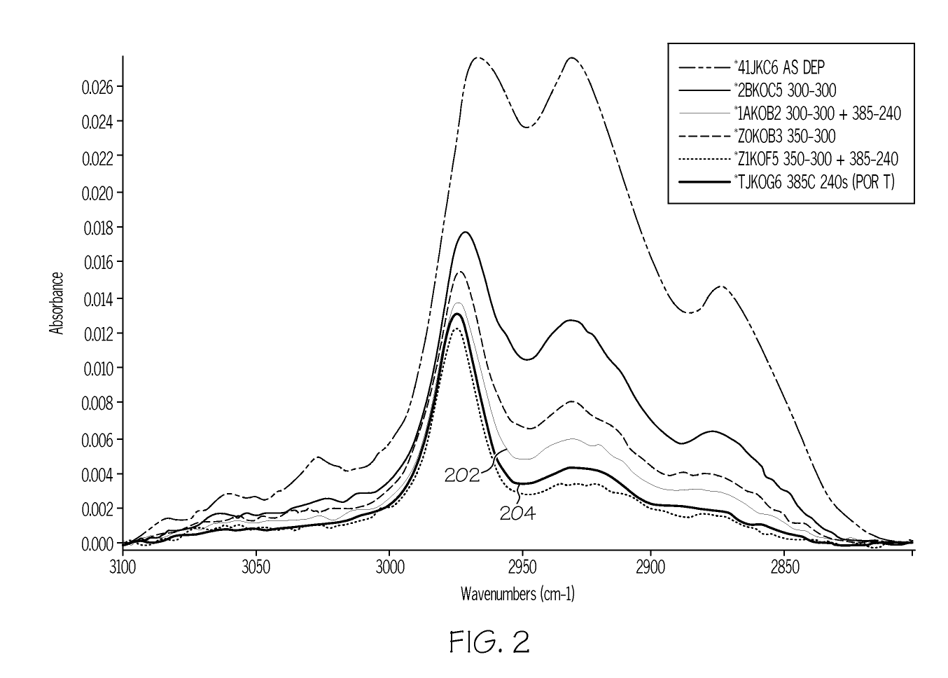

FIG. 2 shows the Fourier transform infrared spectroscopy (FTIR) spectra of 2 materials in the wavelength region from 2800 to 3100 cm-1, the region where C—H bonds absorb. The spectrum 202 was measured from the ULK dielectric material created by the embodiment discussed above. The spectrum 204 was measured from a conventional pSiCOH material that was cured using a single UV cure step. Both materials were created with the same first step, PECVD deposition. Spectrum 202 shows greater absorbance from about 2850 to about 2950 cm-1 compared to spectrum 204, demonstrating that the ULK dielectric material created by the embodiment discussed above comprises more C in the form of —CH2- structures than the conventional pSiCOH material. The peak at 2925 cm-1 is substantially larger in area in spectrum 202, as compared to spectrum 204. It is customary to compare the ratio of the areas under the CHx absorption peaks between 3100 cm-1 to 2800 cm-1 and the SiOx peaks between 1250 and 975 cm-1. Table 3 below shows that this ratio is significantly higher for a film made based on the two-step UV cure process discussed above compared to a film of the same deposition chemistry that was cured according to the conventional single step UV cure process.

TABLE 3

| Sample (k = 2.0-2.1) | 2800-3100 peak | 975-1250 peak | B/C |
|---|---|---|---|
| pSiCOH | area = B | area = C | ratio |
| Inventive | 0.893 | 16.723 | 0.053 |
| material: Two | | | |
| STEP UV cure | | | |
| Conventional | 0.730 | 16.780 | 0.043 |
| pSiCOH: | | | |
| Single step UV | | | |
| cure | | | |

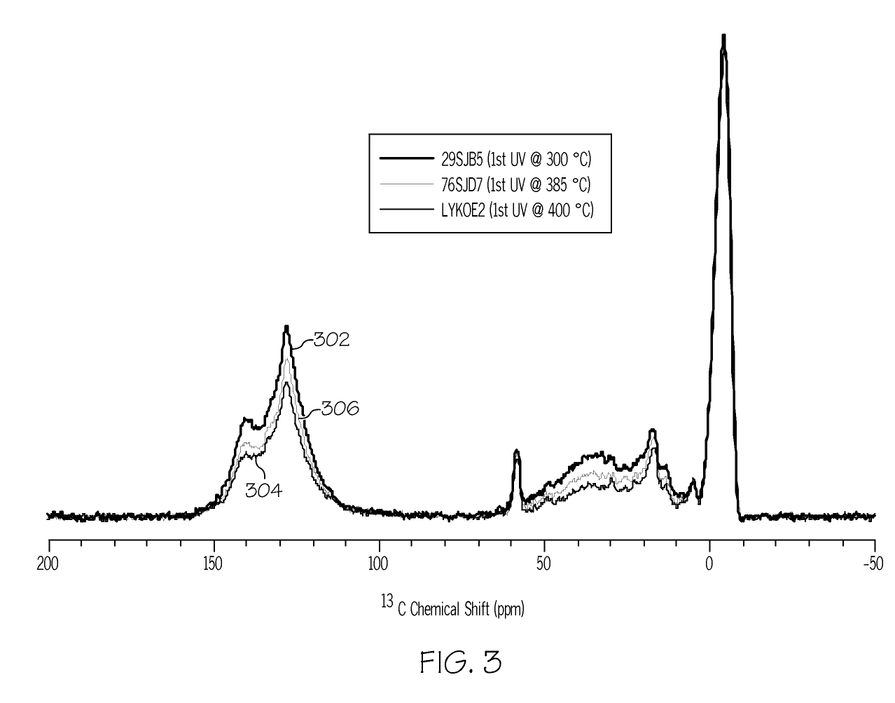

The nuclear magnetic resonance (NMR) spectrum detected from the ¹³C atoms of three different pSiCOH dielectrics is shown in FIG. 3. The spectrum labeled 302 was measured from the ULK dielectric material created by the embodiment discussed above. The spectrum labeled 304 was measured from a conventional pSiCOH material, cured using a single UV cure step. The spectrum labeled 306 was measured from an ULK dielectric material created by the embodiment discussed above, but with the wafer temperature at the second UV curing step being 350° C., which was not an optimum value. The three materials were made with the same first step, PECVD deposition. In the region from 10-50 ppm chemical shift, the top curve is 302, the middle curve is 306, and the lower curve is 304. The area under each spectrum is proportional to the carbon content, and, as can be seen, the inventive pSiCOH material (curve 302) comprises a greater C content than the conventional pSiCOH material, cured using a single UV cure step (curve 304). The peak with a broad maximum at 30 to 40 ppm is substantially larger in area in spectrum 302, as compared to spectrum 304.

It is noted that the material produced in the first embodiment comprises a content of —CH2- groups that is substantially greater than the conventional prior art pSiCOH dielectric. The evidence from FTIR spectra and solid state NMR was given in the preceding two paragraphs.

In addition to the process discussed above, another embodiment of the present invention provides a stable ultra low k SiCOH dielectric material that has a dielectric constant of about 2.2. The pSiCOH dielectric material of this embodiment is formed as follows.

In the deposition process, such as (but not limited to) a PECVD process, a substrate is placed in a PECVD reactor on a heated wafer chuck and a reactive gas mixture is added to the reactor. In one non-limiting example, the substrate is a 300 mm Si wafer and the reactor is a 300 mm production tool. The SiCOH dielectric material is formed by providing at least a first matrix precursor (liquid, gas, or vapor) comprising atoms of Si, C, O, and H, and an inert carrier gas such as He or Ar, into the reactor.

A film is then derived from the first precursor onto a suitable substrate utilizing conditions that are effective in forming the SiCOH dielectric material of at least this embodiment. Also, in one embodiment, the first precursor can be mixed with an oxidizing agent such as O₂, CO₂, or a combination thereof, thereby stabilizing the reactants in the reactor and improving the uniformity of the dielectric film deposited on the substrate. In another embodiment, in addition to the first precursor, the reactive gas mixture also comprises a second porogen precursor (gas, liquid, or vapor) comprising atoms of C, H, and optionally O, F, and N. For example, the second porogen precursor can be, but is not limited to, bicycloheptadiene (BCHD), also called norbornadiene (NBD).

In this embodiment, the wafer chuck temperature at between about 300° C. and about 425° C., e.g., 320° C.; setting the reactor pressure at around 8 Torr; setting the high frequency RF power that is applied to the gas distribution plate between about 75 W and about 1000 W, e.g., 700 W; setting the first precursor flow rate for DEMS to 1075 mg/minute; setting the second porogen precursor flow rate for BCHD to 1450 mg/minute; and setting the flow of an oxidizing gas such as O₂ to between about 10 sccm to about 1000 sccm (e.g., 125 sccm). This process results in a preliminary film of the first embodiment discussed above. It should be noted that these are examples of only one set of settings applicable to embodiments of the present invention and do not limit the present invention in any way.

Once the preliminary film is deposited, the substrate with comprising the preliminary file is transferred to wafer chuck in a UV cure tool (such as, but not limited to a 300 mm production UV cure tool). The UV treatment tool may be connected to the deposition tool (“clustered”), or may be a separate tool. The wafer chuck is heated to a first temperature such as, but not limited to, 300° C. and broad band UV radiation is applied for a given amount of time such as, but not limited, to between about 10 to 1000 seconds (e.g., 300 seconds). This process results in a reaction of a fraction of the porogen phase and removal of a fraction of the porogen phase. The substrate is then transferred to another wafer chuck of a second UV cure tool (or remains on the same wafer chuck within the same UV cure tool). The wafer chuck is then heated to a second temperature such as, but not limited to, 385° C. and broad band UV radiation is applied for a range of time between 10 and 1000 seconds, e.g., 180 seconds, 240 seconds, et.,. This process results in the removal of the majority of the porogen phase.

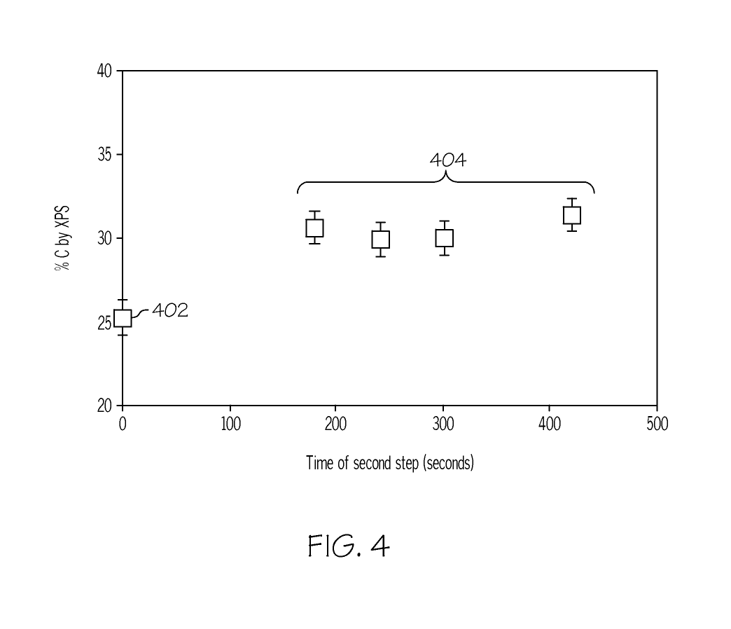

Measurements conducted on the ULK dielectric material of the second embodiment discussed above are as follows. The k value was measured in an aluminum gate MIS structure and was 2.2. The composition (excluding H) was measured by XPS on different samples in which the time of the second curing process was changed from 180 to 420 seconds, and the carbon content was measured by XPS on each sample. The results are shown in FIG. 4, in which the point 402 shows the percentage of C of a conventional pSiCOH material, cured using a single UV cure step. The points labeled 404 show the percentage of C for the different samples made by the second process embodiment discussed above. As can be seen, the ULK dielectric material of the second embodiment discussed above comprises a higher concentration of C as compared to the conventional pSiCOH material.

In yet another embodiment, a stable ultra low k SiCOH dielectric material is formed that has a dielectric constant (or k value) of about 2.3+/−0.1. The deposition process is similar to the embodiments discussed above. By adjusting the conditions in the deposition step, for example using a higher flow of porogen precursor or a lower temperature of deposition, the preliminary film can be adjusted to have a range of porogen content.

Once the preliminary film is deposited, the substrate comprising the preliminary film is transferred to wafer chuck in a UV cure tool, as discussed above. The temperature of the wafer chuck is set at a first temperature, which is 300° C. in this embodiment, and broad band UV radiation is applied at the 300° C. temperature. It should be noted that other temperatures and times may be used for this UV cure step as well. The length of time of this exposure (t) can be used to adjust the final ULK material carbon content, within certain limits. The substrate is then removed from the UV cure tool and the wafer chuck is then increased to a second higher temperature. The substrate with the preliminary film is then placed back into the same UV cure tool and broad band UV radiation is applied for a given amount of time such as, but not limited, to between about 10 to 1000 seconds (e.g., 300 seconds). The curing time of between about 10 to 1000 seconds can be varied depending on the desired properties of the inventive material.

After the second (final) UV cure step, the ULK dielectric material is characterized as having a k value of 2.3+/−0.1, and a % carbon measured by XPS of 25%. A shorter time t and adjusted deposition conditions can be used to produce a ULK dielectric material characterized by a % carbon measured by XPS of approximately 20%. A longer time t and adjusted deposition conditions can be used to produce a ULK dielectric material characterized by a % carbon measured by XPS of approximately 28 to 30%. It should be noted that the C content in this embodiment is greater than convention pSiCOH at the same k value.

In a further embodiment, a stable ultra low k SiCOH dielectric material is formed that has a dielectric constant (or k value) of about 2.0-2.1 (or 2.05+/−0.05). The deposition process is similar to the embodiments discussed above. By adjusting the conditions in the deposition step, for example using a higher flow of porogen precursor or a lower temperature of deposition, the preliminary film can be adjusted to have a range of porogen content.

Once the preliminary film is deposited, the substrate comprising the preliminary film is transferred to wafer chuck in a UV cure tool, as discussed above. The temperature of the wafer chuck is set at a first temperature, which is 300° C. in this embodiment, and broad band UV radiation is applied at the 300° C. temperature. It should be noted that other temperatures and times may be used for this UV cure step as well. The length of time of this exposure (t) can be used to adjust the final ULK material carbon content, within certain limits. The substrate is then removed from the UV cure tool and the wafer chuck is then increased to a second higher temperature. The substrate with the preliminary film is then placed back into the same UV cure tool and broad band UV radiation is applied for a given amount of time such as, but not limited, to between about 10 to 1000 seconds (e.g., 300 seconds). The curing time of between about 10 to 1000 seconds can be varied depending on the desired properties of the inventive material.

After the second (final) UV cure step, the ULK dielectric material is characterized as having a k value of 2.05+/−0.05, and a % carbon measured by XPS of 40%. A shorter time t and adjusted deposition conditions can be used to produce a ULK dielectric material characterized by a % carbon measured by XPS of 35%. A longer time t and adjusted deposition conditions can be used to produce a ULK dielectric material characterized by a % carbon measured by XPS of 45%.

Table 4 below summarizes the increase in C content as measured by XPS for two pairs of pSiCOH films. Each pair is deposited with different PECVD process parameters so that the resulting films of each pair have different k. Within the same pair, the as-deposited film is made with the identical deposition process. In each pair, one of the films is cured with the conventional, single step UV cure, and the other is cured with a two step UV cure, as discussed with respect to various embodiments above.

TABLE 4

| | | | T_{sub} | | XPS | | |
|---|---|---|---|---|---|---|---|
| | T_{sub} | 1^{st} | during | 1^{st} | Composition | | |
| Deposition | during 1^{st} | UV | 2nd UV | UV | (atomic %) | | |
| recipe | UV cure | (sec) | cure | (sec) | C | O | Si |
| k = 2.0 to 2.1 | 300 | 300 | 385 | 300 | 42.2 | 29.1 | 28.7 |
| pSiCOH Two- | | | | | | | |
| step UV cure | | | | | | | |
| k = 2.0 to 2.1 | 385 | 300 | None | 0 | 34.7 | 32.9 | 32.4 |
| pSiCOH | | | | | | | |
| Single step | | | | | | | |
| UV cure | | | | | | | |
| k = 2.2 to 2.3 | 385 | 300 | None | 0 | 18.3 | 46.2 | 35.4 |
| pSiCOH | | | | | | | |
| Single step | | | | | | | |
| UV cure | | | | | | | |
| k = 2.2 to 2.3 | 300 | 300 | 385 | 300 | 22 | 43.1 | 34.8 |
| pSiCOH Two- | | | | | | | |
| step UV cure | | | | | | | |

It should be noted that different first precursors can be used in the embodiments discussed above. For example, the first precursor can be organic molecules with ring structures comprising SiCOH components such as 1,3,5,7-tetramethylcyclotetrasiloxane (“TMCTS” or “C₄H₁₆O₄Si4”), octamethylcyclotetrasiloxane (OMCTS), diethoxymethylsilane (DEMS), dimethyldimethoxysilane (DMDMOS), diethylmethoxysilane (DEDMOS), trimethylsilane (3MS), or any other common alkylsilane or alkoxysilane (cyclic or linear) molecule, e.g., related cyclic and non-cyclic silanes, siloxanes, and the like.

It should also be noted that different second porogen precursors can be used in the embodiments discussed above. For example, many hydrocarbon molecules, alphaterpenene, limonene, hexadiene, and others can be used. One example of the second precursor is a precursor with hydrocarbon molecules comprising ring structures having more than one ring present in the molecule or with branched chains attached to the ring. Especially useful, are species including fused rings, at least one of which includes a heteroatom, such as oxygen. Examples of these species are those that include a ring of a size that imparts significant ring strain, namely rings of 3 or 4 atoms and/or 7 or more atoms. Particularly attractive, are members of a class of compounds known as oxabicyclics, such as cyclopentene oxide (“CPO” or “C₅H₈O”). Also useful are molecules including branched tertiary butyl(t-butyl) and isopropyl(i-propyl) groups attached to a hydrocarbon ring; the ring may be saturated or unsaturated (containing C═C double bonds).

In further embodiments, an optional third precursor may be added to the reactor for the purpose of adding Si—C—Si structures to the inventive material. Examples of precursors used for this include, but are not limited to, bis(dimethoxymethylsilylmethane), [(Trimethylsilyl)methyl]dimethoxy methylsilane, and bis(triethoxylsilyl)methane, although any precursor including the Si—C—Si structure may be used and not only the examples listed above.

Optionally, the third precursor (gas or liquid) may include Ge for the purpose of adding Ge to the inventive material. Optionally, the first or second precursor may contain atoms of F and/or N. Optionally, N₂O, or CO₂ or a combination thereof may be added to the to the gas mixture. While liquid precursors are used in the above embodiments, organosilicon gas phase precursors (such as trimethylsilane) can also be used for the deposition. Also, the conditions used for the first deposition step may vary depending on the desired final dielectric constant of the inventive dielectric material.

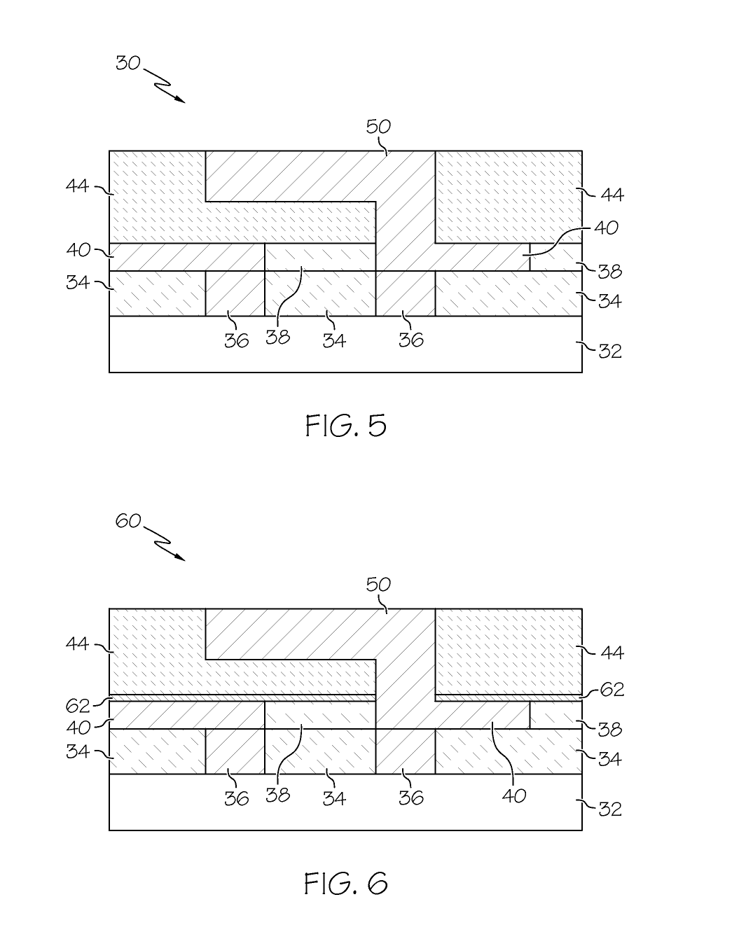

Various electronic devices formed by using the ULK dielectric materials created by the embodiments discussed above are shown in FIGS. 5-8. It should be noted that the devices shown in FIGS. 5 -8 are merely illustrative examples of the present invention, while an infinite number of other devices may also be formed by the various embodiments of the present invention.

In FIG. 5, an electronic device 30 built on a silicon substrate 32 is shown. On top of the silicon substrate 32, an insulating material layer 34 is first formed with a first region of metal 36 embedded therein. After a CMP process is conducted on the first region of metal 36, an ULK SiCOH dielectric film 38 of one or more embodiments of the present invention is deposited on top of the first layer of insulating material 34 and the first region of metal 36. The first layer of insulating material 34 may be suitably formed of silicon oxide, silicon nitride, doped varieties of these materials, or any other suitable insulating materials. The ULK SiCOH dielectric film 38 is then patterned in a photolithography process followed by etching and a conductor layer 40 is deposited thereon. After a CMP process on the first conductor layer 40 is carried out, a second layer of the ULK SiCOH dielectric film 44 is deposited by a plasma enhanced chemical vapor deposition process overlying the first ULK SiCOH dielectric film 38 and the first conductor layer 40. The conductor layer 40 may be deposited of a metallic material or a nonmetallic conductive material. For example, this metallic material or a nonmetallic conductive material can be, but is not limited to, a metallic material of aluminum or copper optionally comprising other elements for improved reliability, or polysilicon. The first conductor 40 is in electrically coupled to the first region of metal 36. Each patterned conductor region typically is surrounded by a diffusion barrier material that is not shown and can be any suitable material, for example, TaN, TiN, Ta.

A second region of conductor 50 is then formed after a photolithographic process on the SiCOH dielectric film 44 is conducted followed by etching and then a deposition process for the second conductor material. The second region of conductor 50 may also be deposited of either a metallic material or a nonmetallic material, similar to that used in depositing the first conductor layer 40. The second region of conductor 50 is electrically coupled to the first region of conductor 40 and is embedded in the second layer of the ULK SiCOH dielectric film 44. Each patterned conductor region typically is surrounded by a diffusion barrier material, not shown, as noted above. The second layer of the SiCOH dielectric film is in intimate contact with the first layer of ULK SiCOH dielectric material 38. In this example, the first layer of the ULK SiCOH dielectric film 38 is an intralevel dielectric material, while the second layer of the ULK SiCOH dielectric film 44 is both an intralevel and an interlevel dielectric. Based on the low dielectric constant of the inventive SiCOH dielectric films, superior insulating properties and capacitance can be achieved by the first insulating layer 38 and the second insulating layer 44.

FIG. 6 shows another embodiment of an electronic device 60 similar to that of electronic device 30 shown in FIG. 5, but with an additional dielectric cap layer 62 deposited between the first insulating material layer 38 and the second insulating material layer 44. The dielectric cap layer 62 can be suitably formed of a material such as silicon oxide, silicon nitride, silicon oxynitride, refractory metal silicon nitride with the refractory metal being Ta, Zr, Hf or W, silicon carbide, silicon carbo-nitride (SiCN), silicon carbo-oxide (SiCO), and their hydrogenated compounds. The additional dielectric cap layer 62 functions as a diffusion barrier layer for preventing diffusion of the first conductor layer 40 into the second insulating material layer 44 or into the lower layers, especially into layers 34 and 32.

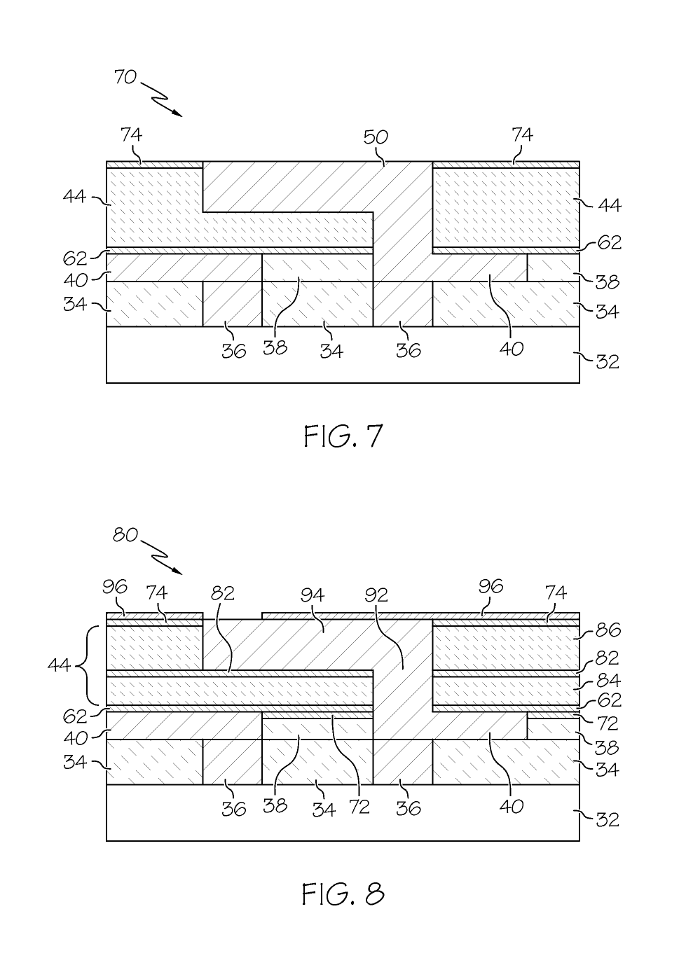

FIG. 7 shows yet another embodiment of the present invention. In particular, FIG. 7 shows an electronic device 70 comprising additional dielectric cap layers 74 that act as a RIE mask and CMP (chemical mechanical polishing) polish stop layer are used. The dielectric cap layer 72 is deposited on top of the first ultra low k insulating material layer 38 and used as a RIE mask and CMP stop, so the first conductor layer 40 and layer 72 are approximately co-planar after CMP. The function of the second dielectric layer 74 is similar to layer 72, however layer 74 is utilized in planarizing the second conductor layer 50. The polish stop layer 74 can be deposited of a suitable dielectric material such as silicon oxide, silicon nitride, silicon oxynitride, refractory metal silicon nitride with the refractory metal being Ta, Zr, Hf, or W, silicon carbide, silicon carbo-oxide (SiCO), and their hydrogenated compounds. An example of a polish stop layer composition is SiCH or SiCOH for layers 72 or 74. A second dielectric layer 74 can be added on top of the second SiCOH dielectric film 44 for the same purposes.

FIG. 8 shows another alternate embodiment of the present invention. In particular, FIG. 8 shows an electronic device 80 comprising an additional layer 82 of dielectric material being deposited and, thus, dividing the second insulating material layer 44 into two separate layers 84 and 86. The intralevel and interlevel dielectric layer 44 formed of the inventive ultra low k material, shown in FIG. 4, is, therefore, divided into an interlayer dielectric layer 84 and an intralevel dielectric layer 86 at the boundary between via 92 and interconnect 94. An additional diffusion barrier layer 96 is further deposited on top of the upper dielectric layer 74. The additional benefit provided by this alternate embodiment electronic structure 80 is that dielectric layer 82 acts as an RIE etch stop providing superior interconnect depth control. Thus, the composition of layer 82 is selected to provide etch selectivity with respect to layer 86. In FIGS. 6-8, it is understood that each patterned conductor region typically is surrounded by a diffusion barrier material, not shown, as noted above (FIG. 5). Based on the low dielectric constant of the SiCOH dielectric films of various embodiments of the present invention, superior insulating properties and capacitance are achieved by the first insulating layer 38 and the second insulating layer 44 in the structures shown in FIGS. 5-8.

Still other alternate embodiments may include an electronic structure which has layers of insulating material as intralevel or interlevel dielectrics in a wiring structure that includes a pre-processed semiconducting substrate which has a first region of metal embedded in a first layer of insulating material, a first region of conductor embedded in a second layer of the insulating material wherein the second layer of insulating material is in intimate contact with the first layer of insulating material, and the first region of conductor is in electrical communication with the first region of metal, a second region of conductor in electrical communication with the first region of conductor and is embedded in a third layer of insulating material, wherein the third layer of insulating material is in intimate contact with the second layer of insulating material, a first dielectric cap layer between the second layer of insulating material and the third layer of insulating material and a second dielectric cap layer on top of the third layer of insulating material, wherein the first and the second dielectric cap layers are formed of a material that includes atoms of Si, C, O and H, or an ULK SiCOH dielectric film of one or more embodiments of the of the present invention.

Additional alternate embodiments of the present invention include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor that is in electrical communication with the first region of conductor and is embedded in a third layer of insulating material, the third layer of insulating material is in intimate contact with the second layer of insulating material, and a diffusion barrier layer formed of the multiphase, ultra low k film of one or more embodiments of the present invention deposited on at least one of the second and third layers of insulating material.

Even further, other alternate embodiments include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a reactive ion etching (RIE) hard mask/polish stop layer on top of the second layer of insulating material, and a diffusion barrier layer on top of the RIE hard mask/polish stop layer, wherein the RIE hard mask/polish stop layer and the diffusion barrier layer are formed of the SiCOH dielectric film of one or more embodiments of the present invention.

Still other alternate embodiments include an electronic structure which has layers of insulating materials as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a first RIE hard mask, polish stop layer on top of the second layer of insulating material, a first diffusion barrier layer on top of the first RIE hard mask/polish stop layer, a second RIE hard mask/polish stop layer on top of the third layer of insulating material, and a second diffusion barrier layer on top of the second RIE hard mask/polish stop layer, wherein the RIE hard mask/polish stop layers and the diffusion barrier layers are formed of the SiCOH dielectric film of one or more embodiments of the present invention.

Further alternate embodiments of the present invention includes an electronic structure that has layers of insulating material as intralevel or interlevel dielectrics in a wiring structure similar to that described immediately above but further includes a dielectric cap layer which is formed of the SiCOH dielectric material of one or more embodiments of the present invention situated between an interlevel dielectric layer and an intralevel dielectric layer.

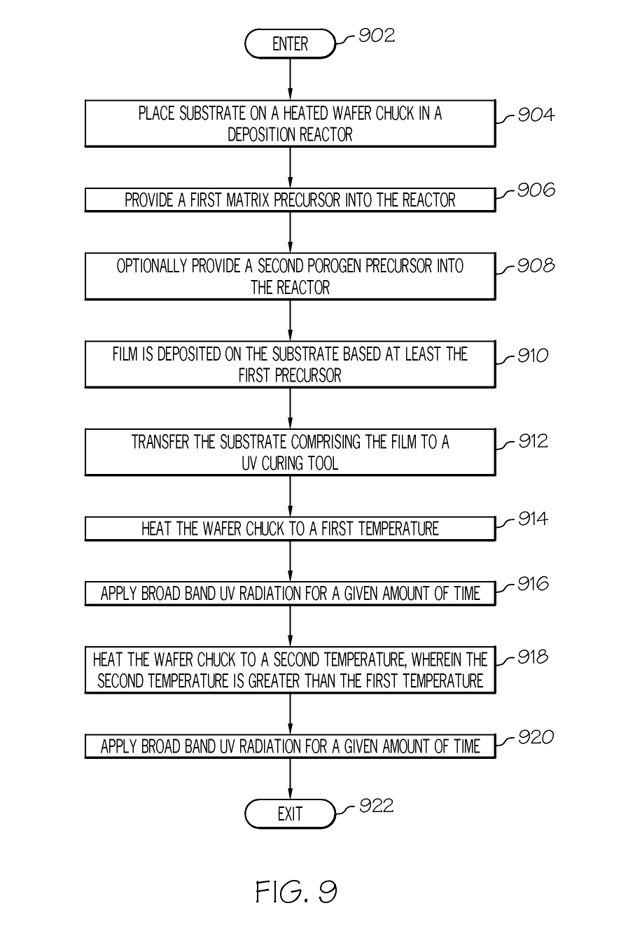

FIG. 9 is an operational flow diagram illustrating one process for creating a ULK SiCOH dielectric material according to one embodiment of the present invention. The process of FIG. 9 begins at step 902 and flows directly to step 904. A substrate, in step 904, is placed on a heated wafer chuck in a deposition reactor. A first matrix precursor, at step 906, is provided into the reactor. A second porogen precursor, at step 908, is optionally provided into the reactor. A preliminary film, at step 910, is formed on the substrate based at least on the first precursor. The substrate comprising the preliminary film, at step 912, is then transferred to a UV curing tool. The wafer chuck comprising the substrate in the UV curing tool, at step 914, is heated to a first temperature. Broad band UV radiation, at step 916, is then applied for a given amount of time while the substrate is at the first temperature. The wafer chuck, at step 918, is then heater (either in the same UV curing tool or in a different UV curing tool) to a second temperature that is greater than the first temperature. Broad band UV radiation, at step 920, is then applied for a given amount of time while the substrate is at the second temperature. This process creates the ULK dielectric material discussed above. The control flow then exits at step 922.

### NON-LIMITING EXAMPLES

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. An ultra low dielectric constant material comprising:
a three dimensional random network porous dielectric comprising atoms of Si, C, O, and H;
a dielectric constant of not more than 2.6;
a carbon concentration of at least 15%; and
a content of carbon that is bonded as —CH2-groups, wherein a concentration of carbon is greater than a concentration of carbon in an ultra low dielectric constant material formed by using a single step ultra-violet curing process.

2. The ultra low dielectric constant material of claim 1, further comprising:
about 5 to about 50 atomic percent of Si;
about 5 to about 40 atomic percent of C; and
about 0 to about 50 atomic percent of O.

3. The ultra low dielectric constant material of claim 1, wherein the concentration of carbon is characterized by an absorbance intensity ratio as measured by Fourier Transform Infrared spectroscopy (FTIR) for CH/SiO, wherein an absorbance intensity ratio associated with the concentration of carbon is greater than an absorbance intensity ratio associated with the concentration of carbon for the ultra low dielectric constant material formed by using a single step ultra-violet curing process.

4. The ultra low dielectric constant material of claim 3, wherein an FTIR absorbance intensity ratio for CH is measured from about 2800 to about 3100 cm-1 and an absorbance intensity ratio for SiO is measured from 975 to 1250 cm-1.

5. The ultra low dielectric constant material of claim 3, wherein the dielectric constant is about 2.1, wherein the absorbance intensity ratio of the ultra low dielectric constant material is greater than 0.05.

6. The ultra low dielectric constant material of claim 1, wherein the dielectric constant is in a range from about 1.8 to about 2.6.

7. The ultra low dielectric constant material of claim 1, wherein the dielectric constant is not more than 2.4, and wherein the carbon concentration is at least 20%.

8. The ultra low dielectric constant material of claim 1, wherein the dielectric constant is not greater than about 2.2, and wherein the carbon concentration is at least 20%.

9. The ultra low dielectric constant material of claim 1, wherein the dielectric constant is not greater than about 2.1, a wherein the carbon concentration is at least 20%.

10. The ultra low dielectric constant material of claim 1, further comprising:
an elastic modulus of greater than about 4 GPa.

11. The ultra low dielectric constant material of claim 1, further comprising:
an elastic modulus of greater than about 3 GPa.

12. The ultra low dielectric constant material of claim 1, further comprising:
an elastic modulus of greater than about 2.5 GPa.

13. A method for fabricating an ultra low dielectric constant material, the method comprising:
placing a substrate into a deposition reactor;
flowing a first precursor into the deposition reactor, wherein the first precursor is a matrix precursor;
flowing a second precursor into the deposition reactor, wherein the second precursor is a porogen precursor;
depositing a preliminary film onto the substrate based on the first and second precursors, wherein the preliminary film comprises Si, C, O, and H atoms;
performing a first ultraviolet curing step on the substrate comprising the preliminary film at a first temperature; and
performing at least a second ultraviolet curing step on the substrate comprising the preliminary film at a second temperature.

14. The method of claim 13, wherein the first precursor comprises at least Si, C, and O atoms, and wherein the second precursor comprises at least C and H atoms.

15. The method of claim 13, wherein the second temperature is higher than the first temperature.

16. The method of claim 13, wherein the matrix precursor is one of:
diethoxymethylsilane;
dimethoxydimethylsilane;
octamethyltetrasiloxane;
tetramethyltetrasiloxane; and
trimethylsilane.

17. The method of claim 13, the matrix precursor is one of:
an alkylsilane molecule;
a cyclic alkoxysilane molecule; and
a non-cyclic alkoxysilane molecule.

18. The method of claim 13, further comprising:
flowing a third precursor into the reactor.

19. The method of claim 18, wherein the third precursor comprises an Si—C—Si structure.

20. The method of claim 13, wherein the second temperature is about between 350° C. to 425° C.

21. The method of claim 13, wherein the porogen precursor is bicycloheptadiene.

22. The method of claim 13, wherein the first temperature is about between 200° C. and 350° C.

23. The method of claim 13, wherein the first and second ultraviolet curing steps are performed using ultraviolet radiation comprising a range of wavelengths including wavelengths greater than about 190 nm and wavelengths less than about 500 nm.

24. An electronic structure comprising one or more layers of insulating material as at least one or intralevel and interlevel dielectrics in a wiring structure comprising:
a pre-processed semi-conducting substrate comprising a first region of metal embedded in a first layer of insulating material;
a first region of conductor embedded in a second layer of insulating material formed of an ultralow-k material, the ultralow-k material comprising Si, C, O and H, and a multiplicity of nanometer-sized pores, wherein the ultralow-k material comprises a dielectric constant of not more than about 2.6 and comprising a carbon concentration of at least 15% and a content of carbon that is bonded as —CH2-groups, wherein a concentration of carbon is greater than a concentration of carbon in an ultra low dielectric constant material formed by using a single step ultra-violet curing process,
wherein the second layer of insulating material being in intimate contact with the first layer of insulating material,
wherein the first region of conductor being in electrical communication with the first region of metal; and
a second region of conductor being in electrical communication with the first region of conductor and being embedded in a third layer of insulating material comprising the ultralow-k material, wherein the third layer of insulating material being in intimate contact with the second layer of insulating material.
